(19) United States
(12) Patent Application Publication
(10) Pub. No.: US 2022/0406620 A1
(43) Pub. Date: Dec. 22, 2022

(54) FABRICATING METHOD FOR WAFER LEVEL SEMICONDUCTOR PACKAGE DEVICE AND THE FABRICATED SEMICONDUCTOR PACKAGE DEVICE

(71) Applicant: PANJIT INTERNATIONAL INC., KAOHSIUNG CITY (TW)

(72) Inventors: Chung-Hsiung Ho, Kaohsiung City (TW); Chih-Hung Chang, Kaohsiung City (TW); Chi-Hsueh Li, Tainan City (TW)

(73) Assignee: PANJIT INTERNATIONAL INC., KAOHSIUNG CITY (TW)

(21) Appl. No.: 17/354,214

(22) Filed: Jun. 22, 2021

(51) Int. Cl. H01L 21/56; H01L 23/00; H01L 23/31; H01L 21/311; H01L 21/78

(52) U.S. Cl. CPC H01L 21/565; H01L 24/13; H01L 24/04; H01L 21/561; H01L 23/3157; H01L 21/31138; H01L 21/78; H01L 24/94; H01L 2224/0401; H01L 2224/13026

(57) ABSTRACT

The invention describes a fabricating method for fabricating semiconductor package device which includes the following steps: providing a wafer having a plurality of dies, wherein each of the dies is provided on a top surface thereof with a middle electric conducting structure and a solder ball; forming a molding structure having a flat top surface on a top side of the wafer; removing a part of the molding structure and exposing a part of each of the solder ball by plasma etching; performing a dicing process along a boundary of each of the dies to separate each of the dies so that the semiconductor package device is thus obtained.

### BACKGROUND OF THE INVENTION

### 1. Field of the Invention

The present invention relates to a fabricating method for semiconductor package device and more particularly, to a fabricating method for semiconductor package device and the fabricated semiconductor package device that can prevent mold flash from attaching to the solder ball.

### 2. Description of the Related Art

Please take reference to FIG. 1A, FIG. 1B and FIG. 2, describing a known fabricating method for fabricating semiconductor package device. Firstly, providing a wafer 80. The wafer 80 is provided with a plurality of dies 81, and each of the dies 81 is provided with a middle electric conducting structure 82, such as under ball metallurgy (UBM), benefit implanting solder balls 83 on the middle electric conducting structure 82. After that, by performing a compression molding process and utilizing a release film to encapsulate each of the dies 81 and expose a part of the solder ball 83. Finally, performing a dicing process to separate each of the dies 81 that is encapsulated.

However, the aforementioned fabricating method for semiconductor package device usually has the following drawbacks: (1) After removing the release film, the surface of the solder ball 83 may be contaminated by mold flash. In order to deal with contamination of mold flash, in ordinary situation, the package device will further undergo a re-melting process to render the molder flash to be enclosed in the solder ball 83. In this manner, the solder ball 83 containing the mold flash may affect the reliability of the package device. Furthermore, the volume of the re-melted solder ball 83 may shrink, so that a gap may be formed between the solder ball 83 and the encapsulating material 84. Moist may seeps into the gap accordingly and it may affect the reliability of the package device finally. (2) During the compression molding process, the exerted force from the mold toward the encapsulating material 84 is limited. In ordinary situation, as shown in FIG. 2, the encapsulating material 84 along with the solder ball 83 may form a cone-like structure. The encapsulating material 84 may extend along a tangent line of the periphery of the solder ball 83, and the exposed part of the solder ball 83 is usually smaller, especially for the two solder balls 83 that are in close proximity. The aforementioned exposed part of the solder ball 83 is difficult to manipulate. Further, if the encapsulant 84 is overstressed by the mold, the solder ball 83 may break from the middle electric conducting structure 82. Thus, the following surface-mount process and the reliability test of the package device may also be impacted.

Thus, the present fabricating method for semiconductor package device is not good enough and still has room for improvement.

### SUMMARY OF THE INVENTION

It is an objective of the present invention to provide a novel fabricating method for semiconductor package device that improves the known fabricating method and overcomes the drawbacks of the related art, avoiding mold flash remaining on the surface of the solder ball, maintaining the surface of the solder ball clean, and increasing the contact area of the solder ball exposed to outside.

To attain the above objective, the present invention provides a fabricating method for wafer level semiconductor package device which is used for fabricating a semiconductor package device. The fabricating method comprises the steps of: providing a wafer having a plurality of dies. Each of the dies is provided on a top side thereof with a middle electric conducting structure disposed on the top side of each of the dies and electrically coupled to each of the dies and a solder ball connected on the middle electric conducting structure. Forming a molding structure having a flat top surface on a top side of the wafer to encapsulate each of the dies and the middle electric conducting structure and the solder ball on each of the dies; Removing a part of the molding structure and exposing a part of the solder ball by plasma etching until the molding structure is etched to be a molding body; The molding body has a base portion and a plurality of protrusive portions; The base portion has a top surface, and each of the protrusive portions is extended from the top surface of the base portion toward a largest circumferential edge of the solder ball in a horizontal direction. The protrusive portions each has an outer periphery; The outer periphery of the protrusive portions each is vertical to the top surface of the base portion; performing a dicing process along a boundary of each of the dies to separate each of the dies; Thus, the semiconductor package device jointly constituted by each of the dies, the middle electric conducting structure and the solder ball on each of the dies and the molding body that is diced is thus obtained.

By means of the aforementioned fabricating method for semiconductor package device, based on the condition that after forming the molding structure, the step of removing a part of the molding structure by plasma etching until a part of the solder ball is exposed is further performed, thus the exposed surface of the solder ball will not attach any encapsulating material of the molding structure, better maintaining the cleanness of the surface of the solder ball, avoiding the problem of mold flash formed during the conventional fabricating method.

Further, the present invention also provides a semiconductor package device structure, which comprises a die, a middle electric conducting structure, a solder ball, and a molding body. The aforementioned die comprises a top surface. The middle electric conducting structure is disposed on the top surface of the die and electrically coupled to the die. The solder ball is disposed on the middle electric conducting structure. The molding body encapsulates a part of the solder ball, the die and the middle electric conducting structure. The molding body comprising a base portion and a protrusive portion. The base portion has a top surface. The protrusive portion is extended from the top surface of the base portion toward a largest circumferential edge of the solder ball in a horizontal direction. The protrusive portion comprises an outer periphery. The outer periphery is vertical to the top surface of the base portion.

Further scope of applicability of the present invention will become apparent from the detailed description given hereinafter. However, it should be understood that the detailed description and specific examples, while indicating preferred embodiments of the invention, are given by way of illustration only, since various changes and modification within the spirit and scope of the invention will become apparent to those skilled in the art from this detailed description.

### BRIEF DESCRIPTION OF THE DRAWINGS

FIG. 1A and FIG. 1B are cross-sectional views of the structure of the wafer in accordance with different steps of the conventional fabricating method for semiconductor package device;

FIG. 2 is a partial enlarge view of FIG. 1B;

FIG. 3 is a flow chart of the embodiment, illustrating the steps of the fabricating method for semiconductor package device;

FIG. 4A to FIG. 4I are cross-sectional views of the semiconductor package device in accordance with each step of the flow chart;

FIG. 5 is a schematic cross-sectional view of the semiconductor package device of the embodiment;

FIG. 6 is a partial enlarge view of FIG. 4; and

FIG. 7 is similar to FIG. 5, illustrating the condition that the plasma etching depth is deeper.

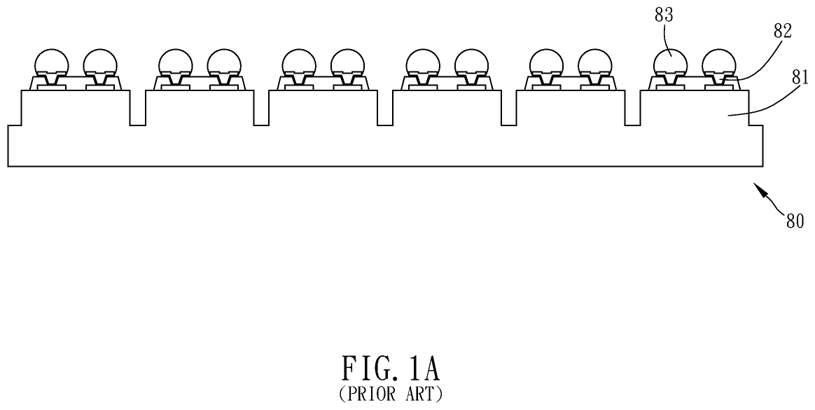

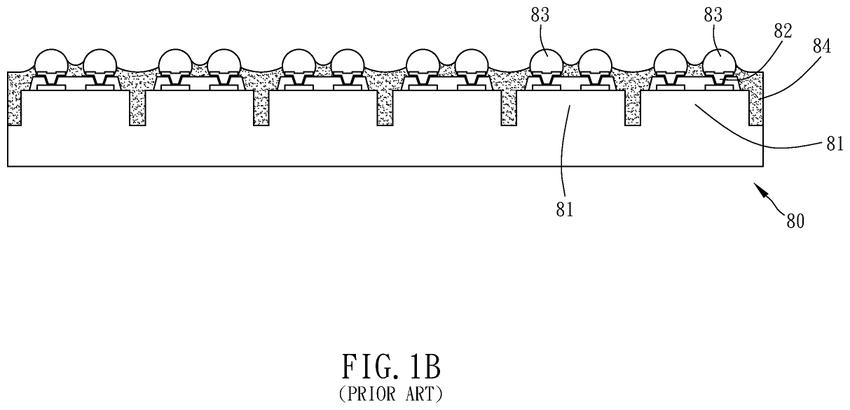

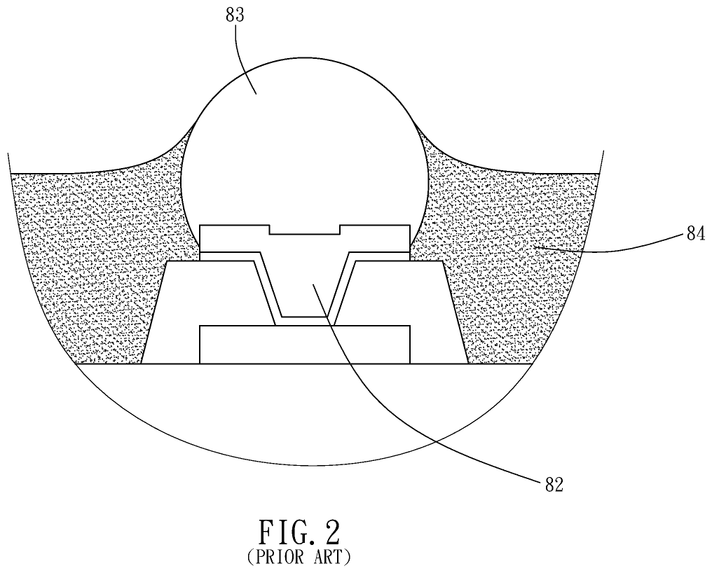

### DETAILED DESCRIPTION OF THE INVENTION

First of all, it is to be mentioned that throughout the entire specification, including the following embodiments and claims, the directional terms such as “up”, “down”, “inside”, “outside”, “top” and “bottom” are based on the direction in the drawings. Besides, in the following embodiments and the appendix drawings, same reference numerals designate same or similar elements or the structural features thereof

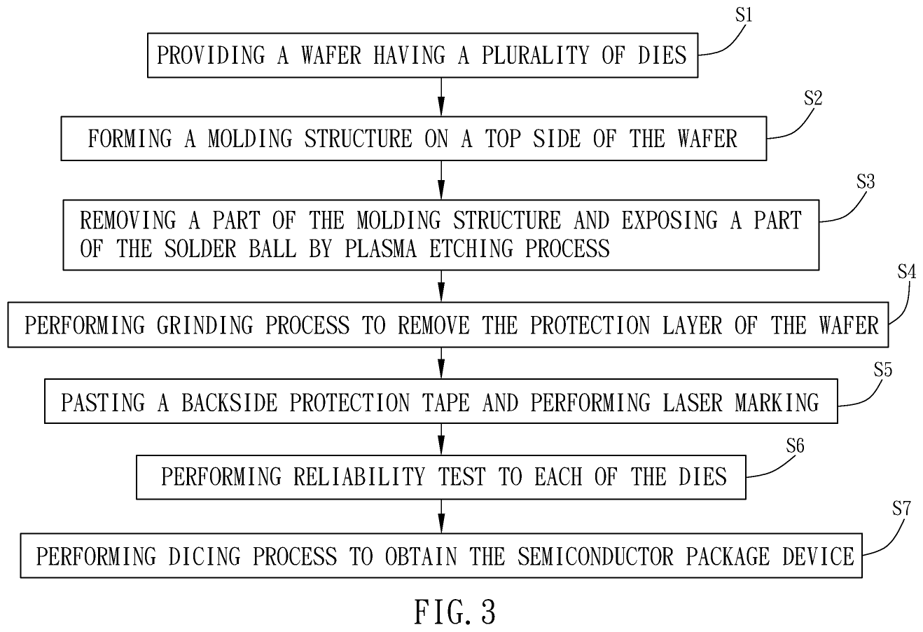

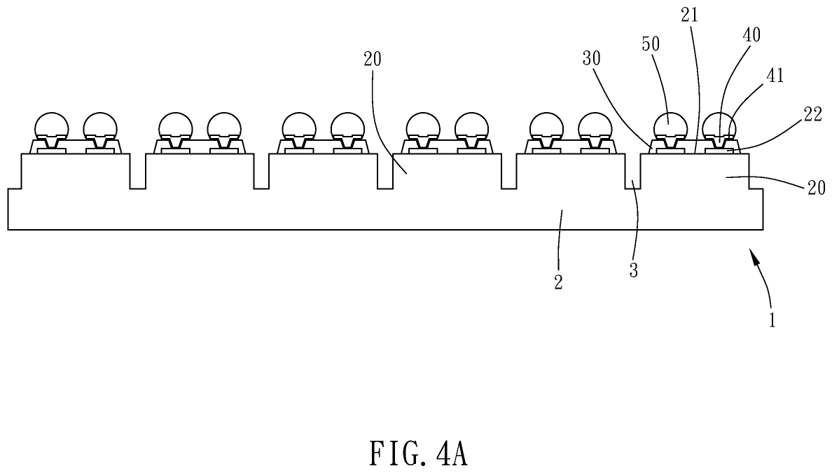

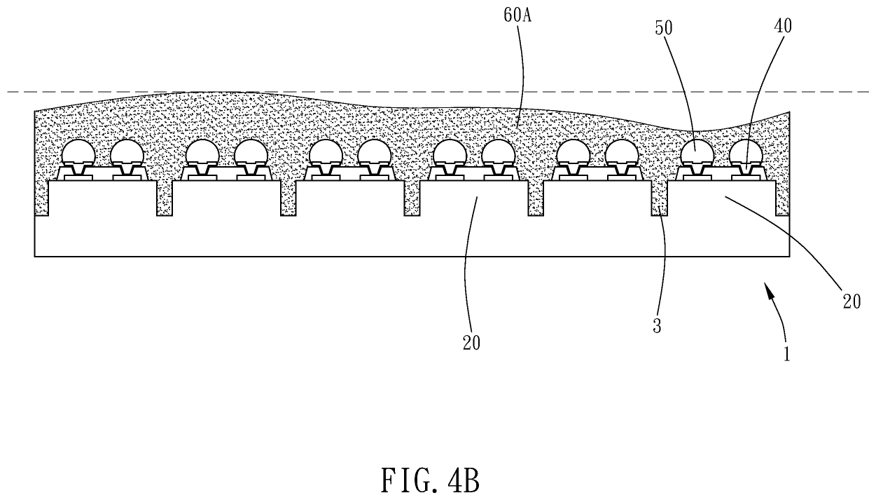

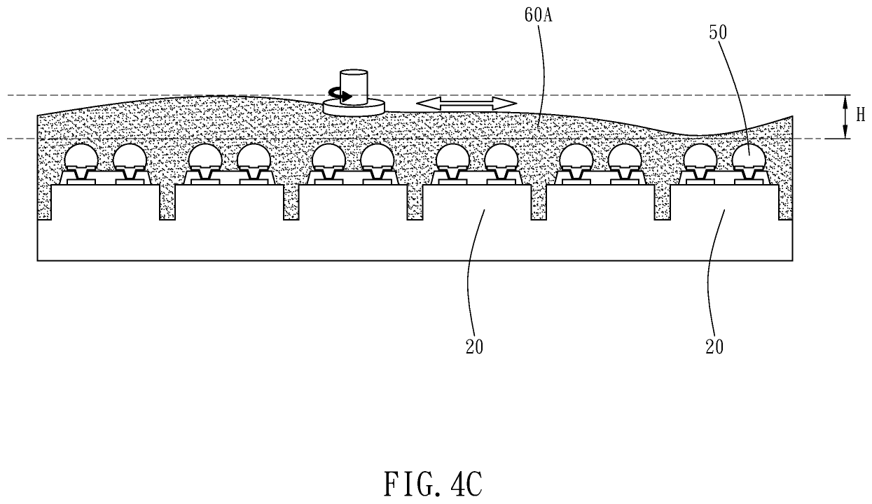

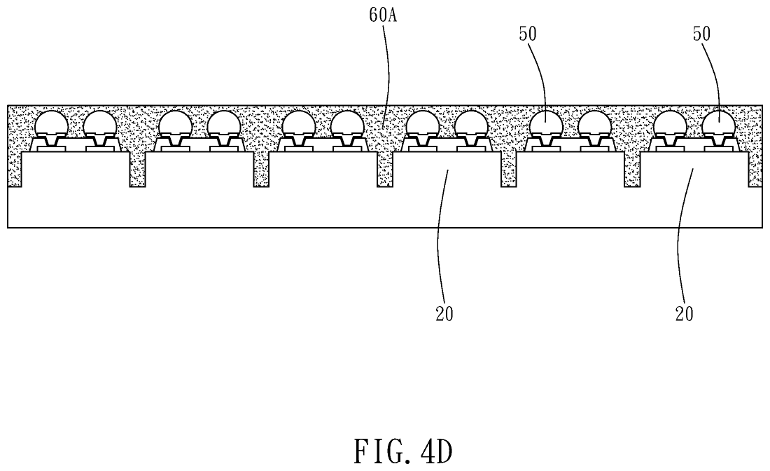

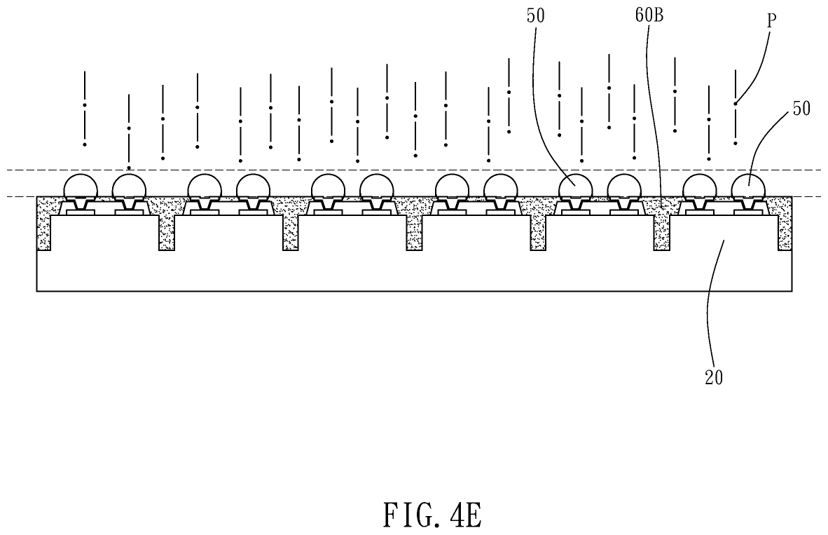

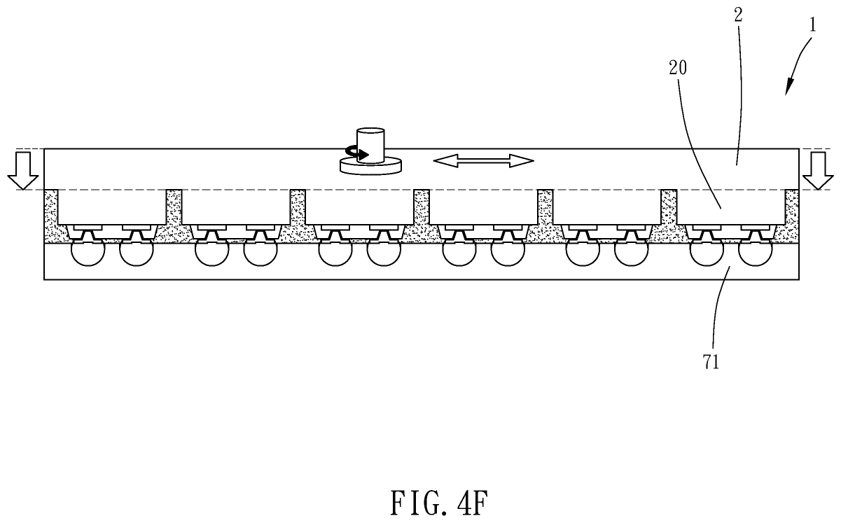

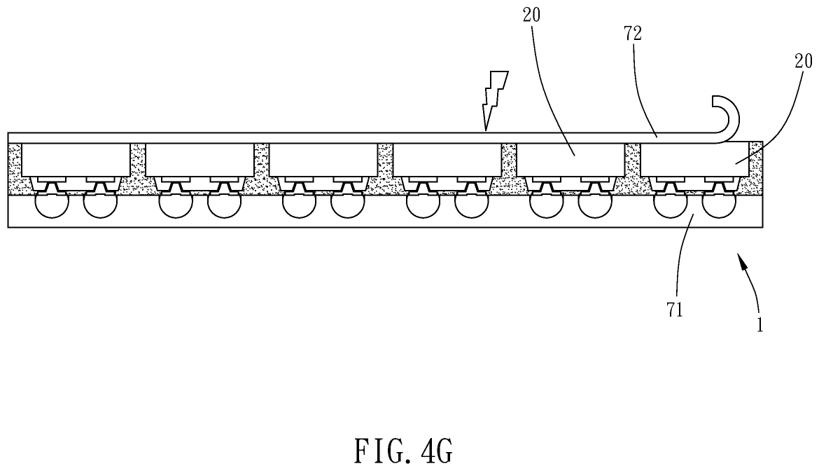

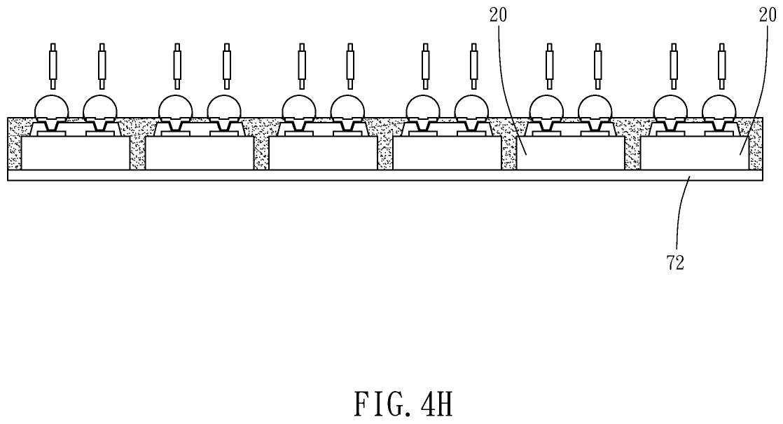

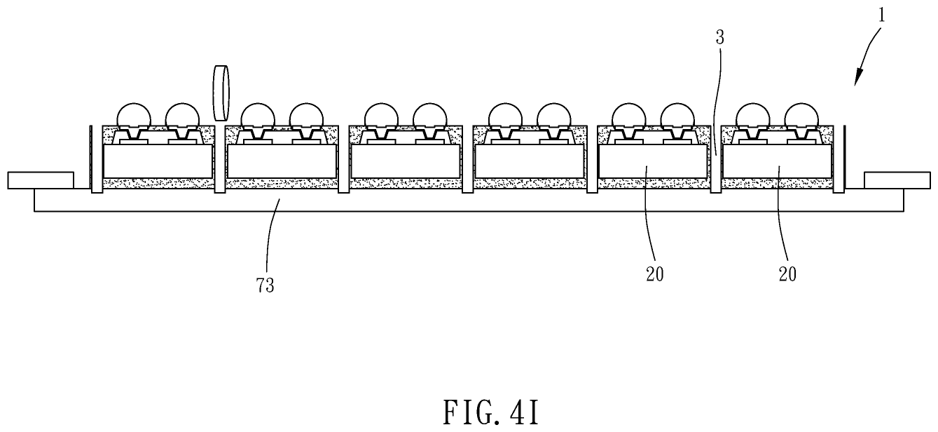

The technical features of the present invention will be specified in the following description of the embodiment and the accompanying drawings. As shown in FIG. 3, FIG. 4A to FIG. 4I, the following embodiment provides a fabricating method for fabricating a plurality of semiconductor package devices 10. The fabricating method comprises the following steps:

Step S1: Providing a wafer 1 (as shown in FIG. 4A). The wafer 1 comprises a protective layer 2 and a plurality of dies 20 connected with the protective layer 2. Each of the dies 20 is provided with a top surface 21 upon which solder pads 22 and a passivation layer 30 are disposed. A middle electric conducting structure 40 is connected on the solder pad 22 and a solder ball 50 is electrically coupled to a top side of the middle electric conducting structure 40. In the present embodiment, the middle electric conducting structure 40 is a under ball metallurgy (UBM). A seed layer 41 is disposed below the UBM. The UBM penetrates the passivation layer 30 and the UBM is electrically connected with the solder pad 22. However, the present embodiment is not limited to it. The middle electric conducting structure 40 may be structured in a combination of a UBM and a redistribution layer (RDL). Further, in the step S1, a sawing process is performed along a boundary of the dies to form a plurality of dicing lane 3.

Step S2: performing a molding process to form a molding structure 60A on a top side of the wafer 1 to encapsulate each of the dies 20 and the middle electric conducting structure 40 and the solder ball 50 on each of the dies 20. The encapsulating material of the molding structure 60A will also fill all of the dicing lanes 3, so the molding structure 60A will also enclose the lateral surface of each of the dies 20. The encapsulating material of the molding structure 60A may adapt epoxy resin. Based on various kind of molding processes, the top surface of the molding structure 60A may be uneven (as shown in FIG. 4B). Thus, in order to render the top surface of the molding structure 60A flattened. A grinding process may be performed to remove a predetermined height of the encapsulating material of the molding structure 60A (as shown in FIG. 4C), so that the top surface of the molding structure that is ground will be flat and close but not contact the apex of the solder ball 50 (as shown in FIG. 4D).

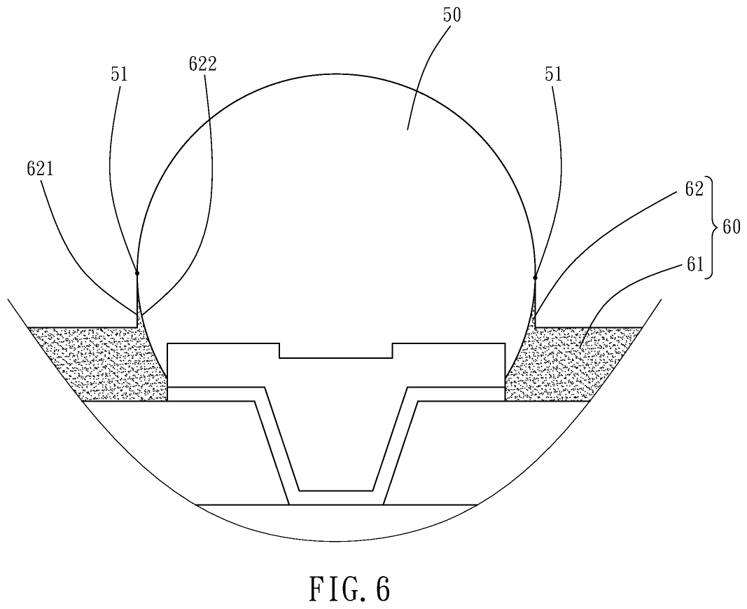

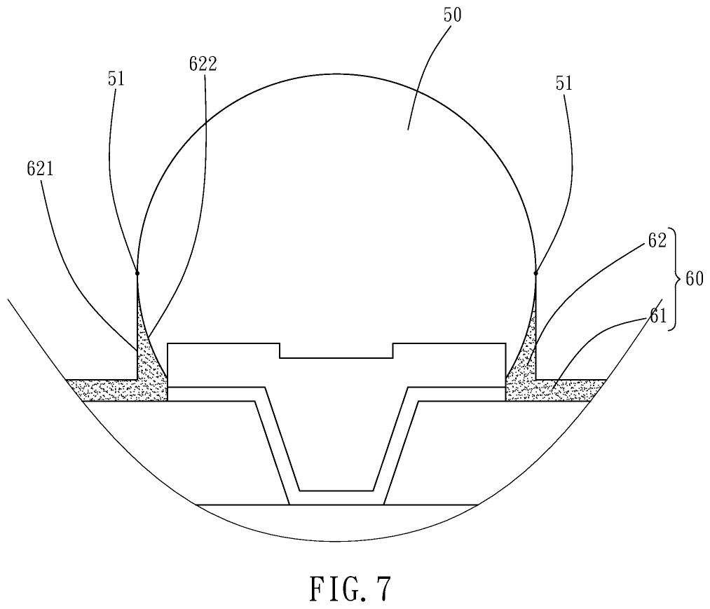

Step 3: In a manner of being vertical to the top surface of the molding structure 60A, removing a part of the molding structure 60A and exposing a part of each solder ball 50 by plasma etching until the molding structure 60A is etched to be a molding body 60B (as shown in FIG. 4E). The molding body 60B comprises a base portion 61 and a plurality of protrusive portions 62 (see FIG. 6). The base portion 61 has a top surface 611. Each of the protrusive portions 62 is extended from the top surface 611 of the base portion 61 toward a largest circumferential edge 51 of the solder ball 50 in a horizontal direction. Each of the protrusive portions 62 encloses and connects a bottom half portion of the solder ball 50 accordingly. The quantity of the protrusive portions 62 is equal to the quantity of the solder balls 50. The protrusive portions 62 each have an outer periphery 621 and an inner concave surface 622 in structure. The height of the outer periphery 621 along with the position of the top surface 611 of the base portion 61 depend on the plasma etching depth. According to different plasma etching depths, for example, if the plasma etching depth is deeper, the height of the protrusions 62 will be higher (as shown in FIG. 7). Based on the condition that the plasma etching process is performed in a manner of being vertical to the top surface of the molding structure 60A, the solder ball 50 per se will be functioning like a mask to allow plasma particles P only etches the encapsulating material on an upper half portion of the solder ball 50. The plasma particles P do not pass through the encapsulating material that is blocked by the solder ball 50, so that the encapsulating material that is blocked is not etched and the outer periphery 621 of each protrusive portion 62 is flush with the largest circumferential edge 51 of the solder ball 50 in the horizontal direction. In an ideal condition, the outer periphery 621 of the protrusive portions 62 will be a cylindrical surface and the outer periphery 621 of each protrusive portion 62 is vertical to the top surface of the solder ball 50. The inner concave surface 621 of each protrusive portion 62 is thoroughly attached to the solder ball 50. Due to no gap existed between the protrusive portion 62 and the solder ball 50, moist will not seep into the package device 10.

Step S4: Pasting a grinding tape 71 on a top side of the wafer 1 which undergoes the plasma etching process. Flipping the wafer 1 and performing a grinding process again to remove the protective layer 2 of the wafer (as shown in FIG. 4F).

Step S5: Pasting a backside protection tape 72 on a bottom surface of the wafer 1 with the protection layer 2 removed and performing laser marking (as shown in FIG. 4G).

Step S6: Removing the grinding tape 71. Prior to dicing each of the dies 20, performing reliability test to each of the dies 20 (as shown in FIG. 4H).

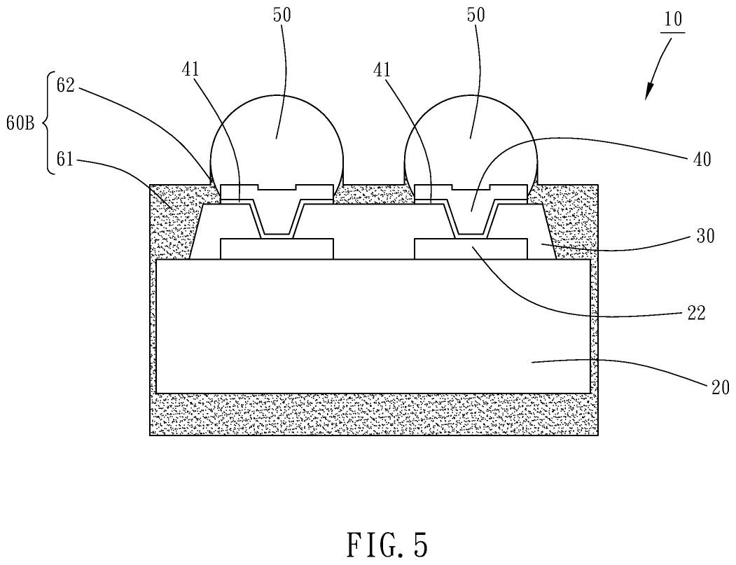

Step S7: Placing the wafer 1 with the protection layer 2 removed on a carrier 73. Performing a dicing process along the boundary (i.e., the sawing lanes 3) of the dies 20 to separate the dies 20 (as shown in FIG. 4I). The desired semiconductor package device 10 which is jointly constituted by the dies 20, the middle electric conducting structure 40 and the solder ball 50 on each of the dies 20, and the molding body 60B that is sawed is thus obtained (as shown in FIG. 5).

It is worthwhile noting that the steps S4 to S6 are performed based on customary needs, so in certain situation, the steps S4 to S6 may not be performed. Further, the step S6 may be performed after the step S7, thus it should not be limited to the present embodiment.

By means of the aforementioned fabricating method for the semiconductor package device, based on the condition that, in the step S3, the fabricated package device 10 undergoes the plasma etching process to remove the encapsulating material until a part of the solder ball 50 is exposed. Thus, the encapsulating material does not remain on the exposed surface of the solder ball 50, effectually maintaining the cleanness of the solder ball 50 and enhancing the overall reliability of the package device 10. Further, in the known compression molding process, owing that the exerted force from the mold toward the encapsulating material is limited, the exposed range of the solder ball in the known compression molding process is smaller. Furthermore, if the encapsulating material is overstressed by the mold in the conventional manner, the solder ball may break from the middle electric conducting material. Compared to that, the fabricating method of the package device of the present embodiment will not have such “the exserted force toward the encapsulating material is limited or the encapsulating material is overstressed” problems. By means of plasma etching process, larger range of the solder ball 50 can be exposed, benefit the following surface mount processes. The technical features of the present embodiment are thus detailed above.

The above content is only used for the description of the embodiment of the present invention. Any variation and modification equivalent to the claims of the present invention should be included within the scope of the present invention.

What is claimed is:

1. A semiconductor package device, comprising:
a die comprising a top surface;
a middle electric conducting structure being disposed on the top surface of the die and electrically coupled to the die;
a solder ball being disposed on the middle electric conducting structure; and
a molding body encapsulating a part of the solder ball, the die and the middle electric conducting structure, the molding body comprising a base portion and a protrusive portion, the base portion having a top surface, the protrusive portion being extended from the top surface of the base portion toward a largest circumferential edge of the solder ball in a horizontal direction, the protrusive portion comprising an outer periphery, the outer periphery being vertical to the top surface of the base portion.

2. The semiconductor package device as claimed in the claim 1, wherein the protrusive portion comprises an inner concave surface, and the inner concave surface is thoroughly attached to the solder ball.

3. The semiconductor package device as claimed in the claim 1, wherein the die further comprises a solder pad; the middle electric conducting structure is a UBM, and the UBM is connected on a top side of the solder pad.

4. The semiconductor package device as claimed in the claim 1, wherein the protrusive portion is enclosed and connected with a bottom half portion of the solder ball.

5. A fabricating method for wafer level semiconductor package device, which is used for fabricating a semiconductor package device, the fabricating method comprising the steps of:
providing a wafer having a plurality of dies, wherein each of the dies is provided on a top side thereof with a middle electric conducting structure disposed on the top side of each of the dies and electrically coupled to each of the dies and a solder ball connected on the middle electric conducting structure;
forming a molding structure having a flat top surface on a top side of the wafer to encapsulate each of the dies and the middle electric conducting structure and the solder ball on each of the dies;
removing a part of the molding structure and exposing a part of the solder ball by plasma etching until the molding structure is etched to be a molding body, wherein the molding body has a base portion and a plurality of protrusive portions; the base portion has a top surface, and each of the protrusive portions is extended from the top surface of the base portion toward a largest circumferential edge of the solder ball in a horizontal direction; the protrusive portions each has an outer periphery; the outer periphery of the protrusive portions each is vertical to the top surface of the base portion;
performing a dicing process along a boundary of each of the dies to separate each of the dies; thus, the semiconductor package device jointly constituted by each of the dies, the middle electric conducting structure and the solder ball on each of the dies and the molding body that is diced is obtained.

6. The fabricating method for wafer level semiconductor package device as claimed in the claim 5, wherein the step of forming the molding structure which has the flat top surface is achieved by performing a grinding process.

7. The fabricating method for wafer level semiconductor package device as claimed in the claim 5, wherein the part of the molding structure is vertically removed relative to the top side of molding structure.

8. The fabricating method for wafer level semiconductor package device as claimed in the claim 5, wherein the step of providing the wafer further comprises performing a sawing process on a boundary of each of the dies to form a plurality of dicing lanes.

9. The fabricating method for wafer level semiconductor package device as claimed in the claim 8, wherein the molding structure fills all of the dicing lanes.
